(19) United States
(12) Patent Application Publication
(10) Pub. No.: US 2026/0206518 A1
(43) Pub. Date: Jul. 16, 2026

(54) THREADED NOZZLE INSERTS

(71) Applicant: Lam Research Corporation, Fremont, CA (US)

(72) Inventors: John Edward Bussan, Sherwood, OR (US); Prasanna Kulkarni, Tigard, OR (US); Rachel E. Batzer, Tigard, OR (US); Tongtong Guo, Lake Oswego, OR (US); Vamshi Krishna Chitikase, Bengaluru (IN); Ching-Yun Chang, West Linn, OR (US); Bo Gong, Sherwood, OR (US)

(21) Appl. No.: 19/137,102

(22) PCT Filed: Dec. 8, 2023
(86) PCT No.: PCT/US2023/083205

§ 371 Date: Jun. 9, 2025

Related U.S. Application Data
(60) Provisional application No. 63/386,882, filed on Dec. 9, 2022.
(60) Provisional application No. 63/509,227, filed on Jun. 20, 2023.

(51) Int. Cl. H10P 72/00

(52) U.S. Cl. CPC H10P 72/0402

(57) ABSTRACT

Threaded nozzle inserts for use in semiconductor processing tool showerheads or gas distributors are disclosed. Such threaded nozzle inserts may, in some cases, include a head portion that has a first face surface and a second face surface parallel to the first face surface and having an outer perimeter that is substantially the same size and shape as an outer perimeter of the first face surface. Such threaded nozzle inserts may also include a shaft portion extending from the second face surface, where a first sub-portion of the shaft portion may be threaded along its length and may have a diameter smaller than a maximum dimension of the second face surface, and may also include a gas distribution hole that extends through the head portion and the shaft portion and along a direction perpendicular to the second face surface.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools often include a showerhead or other gas distributor that is designed to receive one or more process gases via a corresponding inlet or inlets and then distribute that process gas or those process gases across a wafer being processed via a plurality of gas distribution ports distributed across the underside of the showerhead (or other gas distributor).

Disclosed herein are improvements relevant to such showerheads or gas distributor systems.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a head portion and a shaft portion. The head portion may have a first face surface, a second face surface parallel to the first face surface and substantially the same size and shape as the first face surface, and at least two side surfaces that are interposed between the first face surface and the second face surface. The shaft portion may extend from the second face surface, and a first sub-portion of the shaft portion may be threaded along its length and may have a diameter smaller than a maximum dimension of the second face surface. A gas distribution hole may extend through the head portion and the shaft portion and along a direction perpendicular to the second face surface.

In some implementations, the gas distribution hole may have a first diameter at at least one location in between the first face surface and the second face surface and a second diameter larger than the first diameter where the gas distribution hole exits the shaft portion.

In some implementations, the first diameter may be between 0.005″ and 0.03″.

In some implementations, the second diameter may be between 0.02″ and 0.14″.

In some implementations, the first sub-portion of the shaft portion may be threaded with a 10-32 thread.

In some implementations, a second sub-portion of the shaft portion located in between the first sub-portion of the shaft portion and the second face surface may have a diameter of 0.15″ or less.

In some implementations, a transition between the shaft portion and the head portion may have a radius of 0.05″ or less.

In some implementations, a distance between the first face surface and the second face surface may be between 0.03″ and 0.2″.

In some implementations, the shaft portion may extend between 0.2″ and 0.3″ from the second face surface.

In some implementations, there may be at least six side surfaces defining a generally hexagonal shape.

In some implementations, the second face surface may intersect with the six side surfaces at a chamfered edge.

In some implementations, the first face surface may intersect with the six side surfaces at a rounded edge.

In some implementations, the apparatus may further include six curved side surfaces, each curved side surface interposed between two of the six side surfaces and each curved side surface concentric and co-radial with the other curved side surfaces.

In some implementations, the head portion and the shaft portion may be made from an aluminum alloy or from a ceramic.

In some implementations, the head portion and the shaft portion may be made from a 6061-T6 aluminum alloy.

In addition to the above-listed implementations, other implementations evident from the discussion below and the Figures are to be understood to also fall within the scope of this disclosure.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an isometric view of an example threaded nozzle insert for a showerhead of a semiconductor processing tool.

FIG. 2 is a front view of the example threaded nozzle insert of FIG. 1.

FIG. 3 is a rear view of the example threaded nozzle insert of FIG. 1.

FIG. 4 is a right side view of the example threaded nozzle insert of FIG. 1.

FIG. 5 is a left side view of the example threaded nozzle insert of FIG. 1.

FIG. 6 is a top view of the example threaded nozzle insert of FIG. 1.

FIG. 7 is a bottom view of the example threaded nozzle insert of FIG. 1.

FIG. 8 is a section view of the example threaded nozzle insert of FIG. 1 taken along the section line indicated in FIG. 6.

FIG. 9 is a detail view of the circled region of FIG. 8.

FIGS. 10A and 10B depict isometric and cross-sectional views, respectively, of an alternate threaded nozzle insert design.

FIGS. 11A and 11B depict isometric and cross-sectional views, respectively, of another alternate threaded nozzle insert design.

The above-described Figures are provided to facilitate understanding of the concepts discussed in this disclosure, and are intended to be illustrative of some implementations that fall within the scope of this disclosure, but are not intended to be limiting—implementations consistent with this disclosure and which are not depicted in the Figures are still considered to be within the scope of this disclosure.

### DETAILED DESCRIPTION

Semiconductor processing tools are often configured to distribute one or more process gases across a semiconductor wafer during one or more phases of semiconductor processing operations. Such gas distribution is often accomplished through the use of a showerhead or gas distributor (hereinafter, the term “showerhead” herein will be understood to refer to showerheads as well as other gas distributors that may be used to distribute process gases within a semiconductor processing chamber). Such showerheads may have a plurality of gas distribution ports that are distributed along the underside thereof.

In many such showerheads, the gas distribution ports are holes that are machined directly into the underside of the showerhead, thereby providing a flat or smooth underside to the showerhead that has a large number of apertures extending therethrough.

However, other types of showerheads may be designed to have removable nozzle inserts that are threaded into threaded holes on the showerheads. In such implementations, the showerheads themselves may have at least some gas distribution ports that terminate in a larger, threaded hole that is not sized to provide a desired gas delivery profile. Prior to use, such showerheads may have a plurality of threaded nozzle inserts that are threaded into such threaded holes. The use of threaded nozzle inserts may increase the expense of manufacturing such showerheads, as multiple machining steps are needed for each threaded hole as compared with one or two hole-drilling operations for gas distribution port nozzles that are machined directly into the showerhead. Further expense is involved since the inserts themselves must be machined and then installed. However, the use of threaded nozzle inserts also provides several significant benefits. For example, such threaded nozzle inserts are removable and may therefore be easily replaced, e.g., if a nozzle becomes partially occluded due to build-up of deposition byproducts or enlarged due to exposure to etchants. Additionally, there is a risk in a showerhead that has gas distribution port holes drilled directly in the showerhead that one or more such gas distribution holes may be too large, e.g., out of tolerance. If threaded nozzle inserts are used, it is possible to simply replace any out-of-tolerance threaded nozzle insert with a new threaded nozzle insert. Such an approach avoids potentially needing to scrap the entire showerhead part due to it being out of tolerance.

Threaded nozzle inserts have been used in past semiconductor processing systems, but typically in the context of providing for nozzles having exit holes that are significantly offset from the underside of the showerhead. Such threaded nozzle inserts, for example, may protrude from the underside of the showerhead by over 0.5″, e.g., by 0.75″, in order to provide separation distance between the underside of the showerhead and the plane that the exit holes of the nozzles are in. The present threaded nozzle inserts, by contrast, may be relatively low-profile, protruding from the underside of the shower head by a small amount, e.g., between 0.03″ and 0.2″. This allows the threaded nozzle inserts to protrude into the space under the showerhead by a minimal amount while still being able to be interfaced with a wrench or other implement that may be used to tighten or loosen the threaded interfaces of the threaded nozzle inserts.

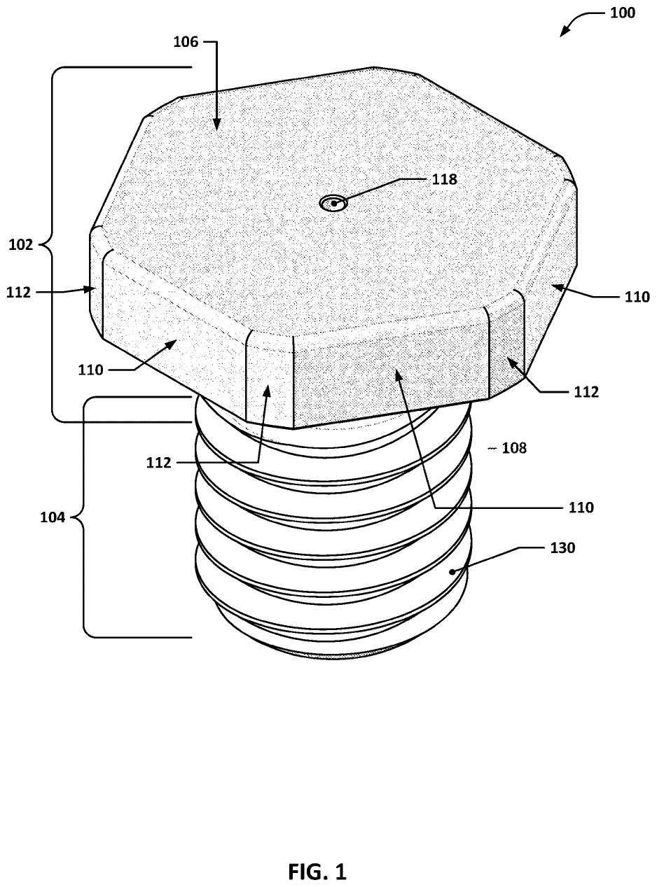

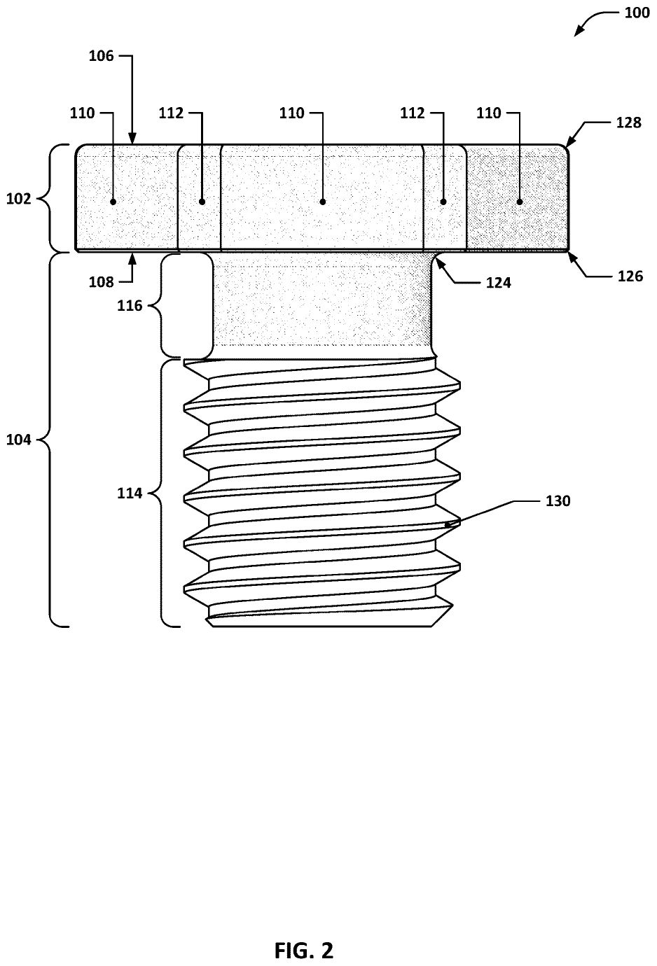

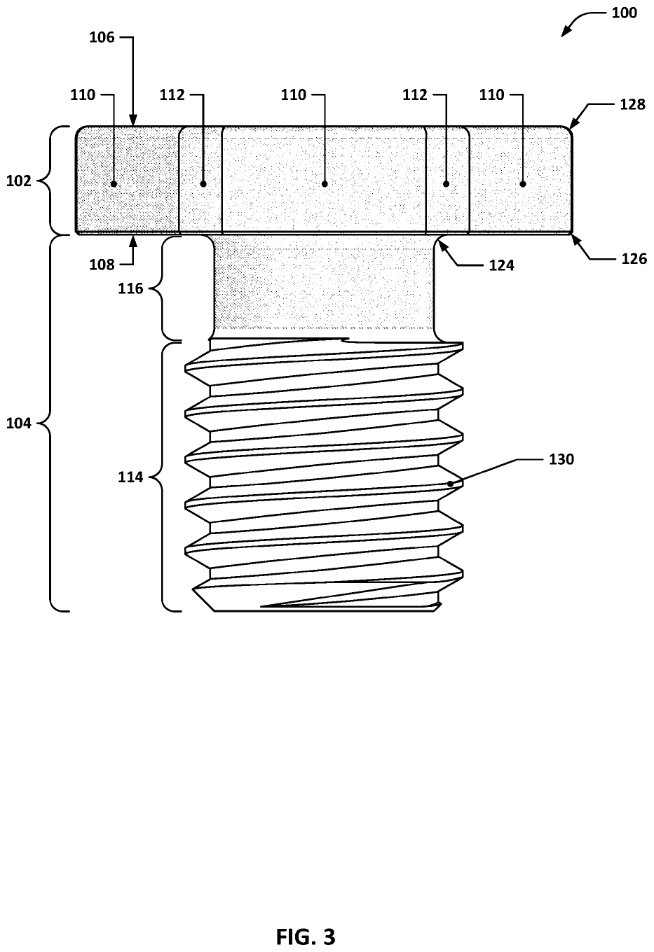

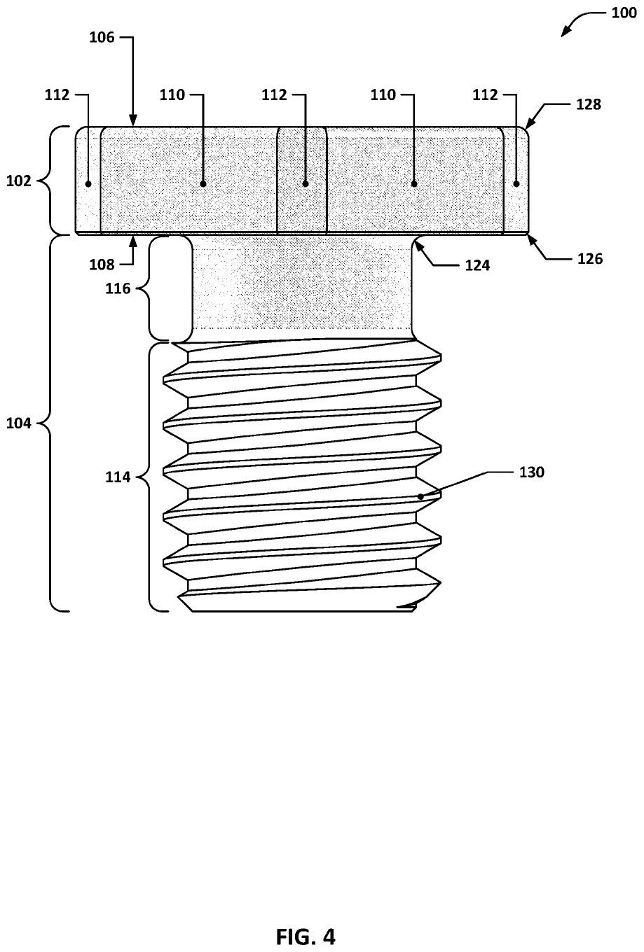

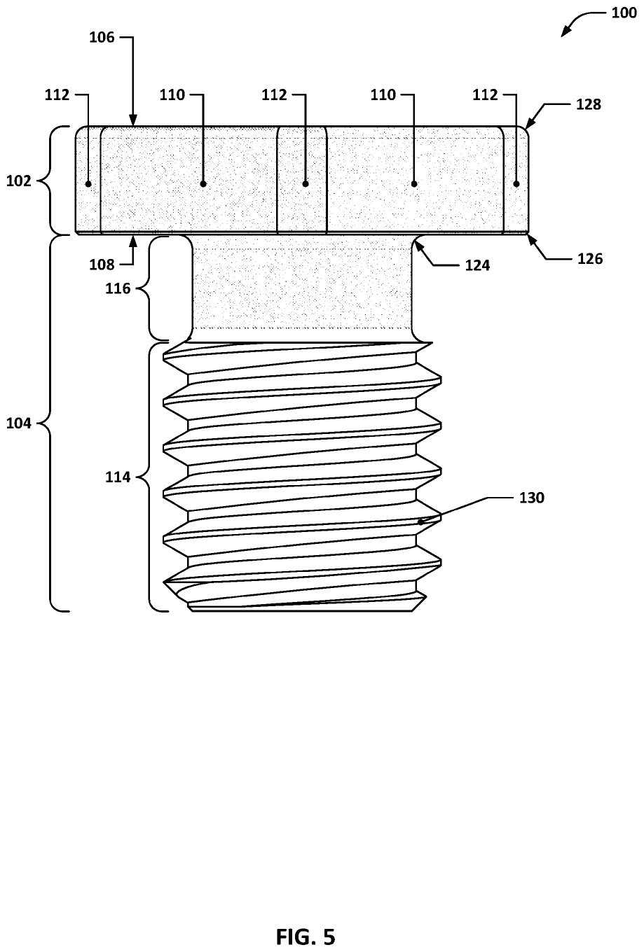

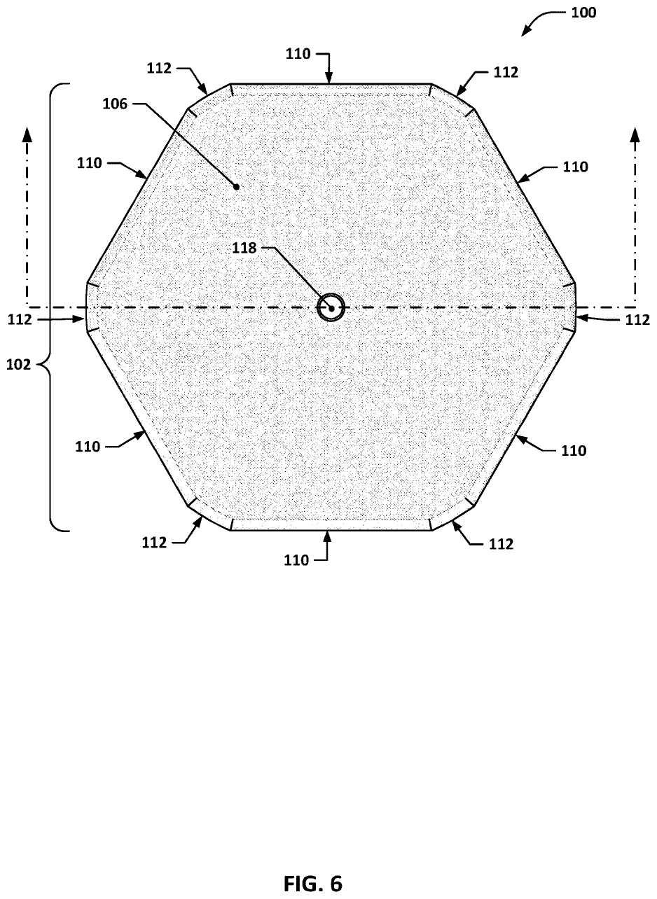

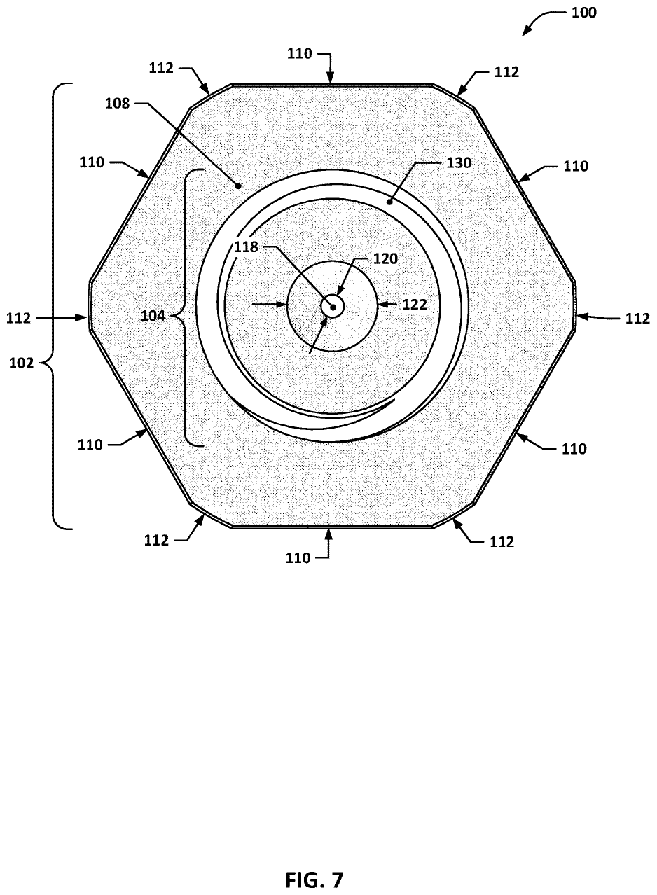

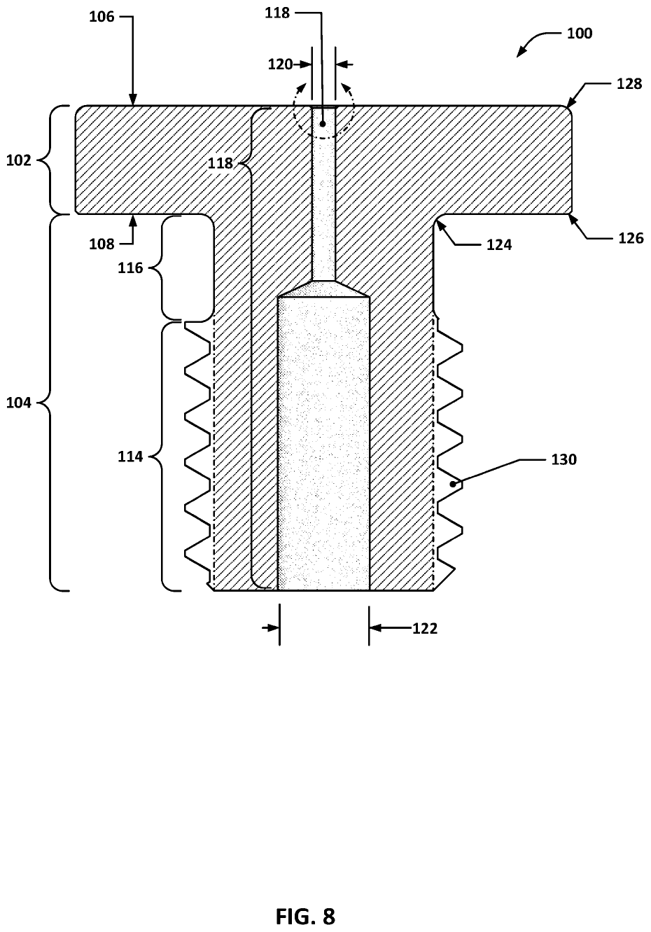

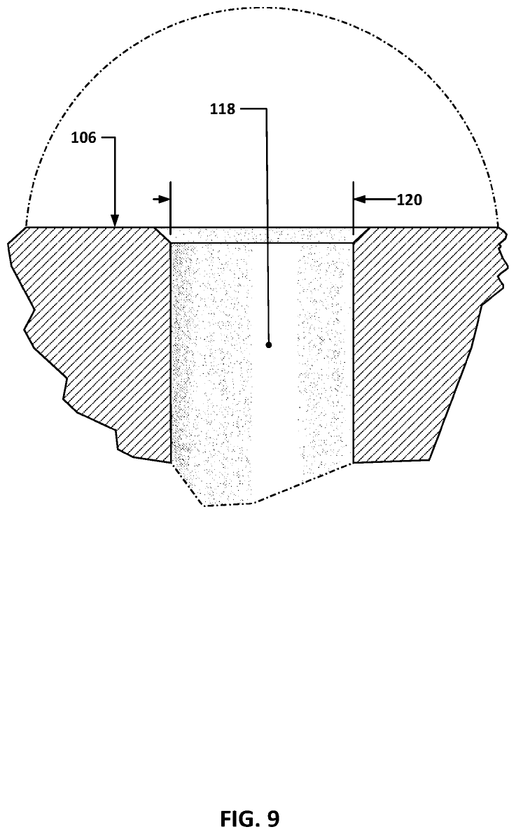

FIGS. 1 through 9 depict various views of an example threaded nozzle insert. FIG. 1 depicts an isometric view of an example threaded nozzle insert for a showerhead of a semiconductor processing tool. FIGS. 2-5 provide front, rear, right-, and left-side views of the threaded nozzle insert of FIG. 1, while FIGS. 6 and 7 depict top and bottom views, respectively, of the threaded nozzle insert of FIG. 1. FIG. 8 depicts a section view of the threaded nozzle insert of FIG. 1 along the section line shown in FIG. 6, while FIG. 9 depicts a detail view of the region of FIG. 8 that is circled.

As can be seen, a threaded nozzle insert 100 is depicted in FIGS. 1 through 9. The threaded nozzle insert 100 may have a head portion 102 and a shaft portion 104. The head portion 102 may have a first face surface 106 that is designed to face towards a semiconductor wafer when the threaded nozzle insert 100 is installed in a showerhead and used to deliver process gases to the semiconductor wafer. The threaded nozzle insert 100 may also have a second face surface 108 that is parallel to the first face surface 106 and substantially the same size and shape as the first face surface 106. The first face surface 106 and the second face surface 108 may thus be, in effect, endcaps of a prismatic solid, such as a generally hexagonal-shaped prismatic solid. As noted above, the thickness of the head portion 102, e.g., the distance between the first face surface 106 and the second face surface 108, may be relatively thin, e.g., less than 0.2″. In some such cases, this distance may be between 0.03″ and 0.2″.

The threaded nozzle insert may also include a plurality of side surfaces 110 that are interposed between the first face surface 106 and the second face surface 108, e.g., generally spanning between the first face surface 106 and the second face surface 108. In some implementations, there may be six side surfaces 110 defining a generally hexagonal shape, although other implementations may have other numbers of side surfaces 110, e.g., four, five, seven, or more side surfaces 110. The side surfaces 110 may, for example, define sides of a regular polygon and may, in some implementations, include at least two side surfaces 110 that are parallel to one another. In some implementations, the side surfaces 110 may be planar in nature, i.e., flat. In some additional implementations, the threaded nozzle insert 100 may further include a plurality of curved side surfaces 112. Each curved side surface 112 may, for example, be circumferentially interposed between a different pair of adjacent side surfaces 110. In some such implementations, the curved side surfaces 112 may have arcuate shapes that are concentric and co-radial in nature. In some implementations, sets of opposing side surfaces 110 may be spaced apart by a distance such as approximately 0.3″ or 0.4″. The side surfaces 110 of the head portion 102 may, in some cases, intersect with the first face surface 106 and/or the second face surface 108 at a chamfered and/or rounded edge. For example, the side surfaces 110 of the head portion 102 may intersect with the first face surface 106 at a rounded edge 128 and with the second face surface 108 at a chamfered edge 126. Such rounded transitions may act to prevent or reduce the potential generation of particulate contaminants that may cause on-wafer defects.

The shaft portion 104 may extend outward from the second face surface 108, away from the first face surface 106. The shaft portion 104 may have a first sub-portion 114 thereof that is threaded with threads 130 along its length in order to allow the threaded nozzle insert to be threaded into a threaded hole in a showerhead faceplate. The threads 130 may, for example, be threads 130 such as 10-32 UNF threads. In some implementations, the shaft portion 104 may include a second sub-portion 116 as well. The second sub-portion 116 may be interposed between the first sub-portion 114 and the second face surface 108 and may be free of threads along its length. In some such implementations, e.g., in such an implementation in which the threads 130 are 10-32 UNF threads, the second sub-portion 116 may be sized to have a diameter of 0.15″ or less.

In some implementations, the shaft portion 104 may extend away from the second face surface 108 by a distance of between 0.2″ and 0.3″, e.g., approximately 0.25″.

Regardless of the specific implementation, the threaded nozzle insert 100 may also include a gas distribution hole 118 that extends through the threaded nozzle insert 100 along a direction perpendicular to the second face surface 108, i.e., through the head portion 102 and through the shaft portion 104. The gas distribution hole 118 may, for example, be a round hole that has a first diameter 120, which may be the minimum diameter of the gas distribution hole 118, in a region between the first face surface 106 and the second face surface 108. In some cases, the portion of the gas distribution hole 118 that has the first diameter 120 may transition to a larger, second diameter 122 at a location within the threaded nozzle insert 100. For example, the gas distribution hole 118 may be the second diameter 122 where it exits the shaft portion 104. In some implementations, the first diameter may be between 0.005″ and 0.03″ and the second diameter, if present, between about 0.02″ and 0.14″. Such a transition may, for example, be by way of a conical intermediate surface that spans between the two different-sized portions of the gas distribution hole 118. In some implementations, the gas distribution hole 118 may have a chamfered edge where it exits the first face surface 106.

In some implementations, the threaded nozzle insert 100 may have a transition 124 where the shaft portion 104 intersects with the second face surface 108 that is rounded or radiused. In some such implementations, the transition 124 may be radiused with a radius of 0.05″ or less.

The second surface 108, it will be recognized, may be sized large enough that it is able to contact and compress against the flat underside of a showerhead that the threaded nozzle insert is to be threaded into, thereby effectively sealing off the threaded interface between the threaded nozzle insert and the showerhead from potential exposure to processing gases that may generate particulates when interacting with sharp edges, e.g., such as the sharp edges of the threads.

The threaded nozzle inserts discussed herein may be machined from any suitable material, e.g., material that is chemically compatible with the processing gases that are to be flowed therethrough and able to withstand the processing conditions, e.g., temperature, expected to be reached during semiconductor processing operations. For example, the threaded nozzle inserts may be made from a material such as an aluminum alloy, such as 6061-T6 aluminum alloy. In some other implementations, the threaded nozzle inserts may be made from a ceramic, such as aluminum oxide.

Threaded nozzle inserts such as those discussed herein may, in particular, offer reduced particulate contamination when used in showerheads for some semiconductor processes. For example, when used in place of substantially longer nozzle inserts, e.g., ones that were on the order of more than 0.5″ in length, particulate contaminant on the wafers being processed was observed to fall by as much as 98% for a given amount of total deposition as compared with when the longer nozzle inserts were used to provide a similar amount of total deposition.

It will be understood that threaded nozzle inserts such as the threaded nozzle insert 100 may also be provided in various formats. The threaded nozzle insert 100 features a hexagonal head portion that allows it to be torqued into place using a box wrench. However, such an arrangement, as can be seen from FIG. #LL, results in the head portion of the threaded nozzle insert protruding from the first side of the showerhead. While the amount of such protrusion is relatively minor, it may nonetheless be preferable to use threaded nozzle inserts that may be flush with the first side of the showerhead, or at least lower-profile than the threaded nozzle inserts 100.

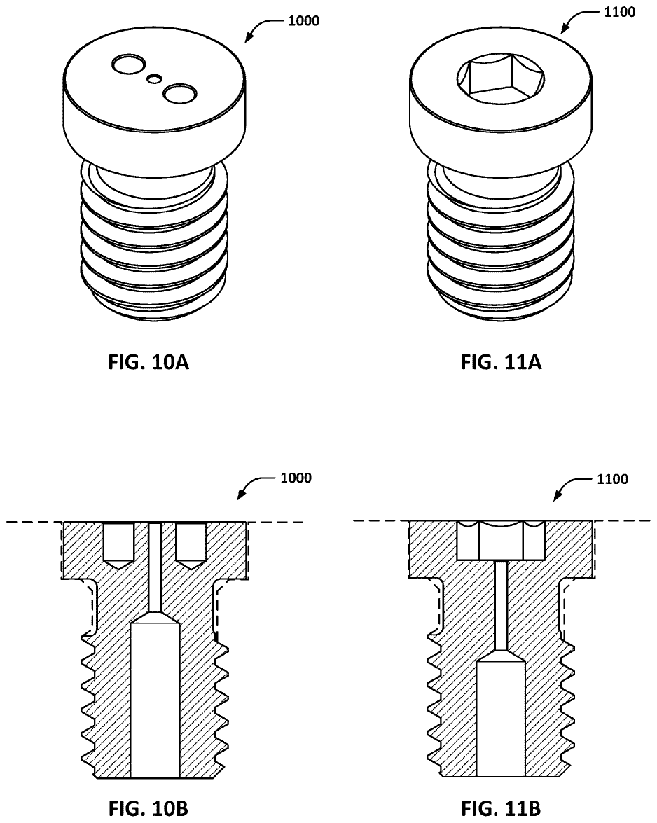

FIGS. 10A and 10B depict isometric and cross-sectional views, respectively, of an example of such a threaded nozzle insert. As can be seen, the threaded nozzle insert 1000 does not have a hexagonal head portion, but instead has a round head portion. The threaded orifice on the showerhead that the threaded nozzle insert 1000 is screwed into may have a counterbore feature (as indicated by the dashed broken lines in FIG. 10B) that allow the threaded nozzle insert 1000 to be screwed into the showerhead such that the top face of the head portion is flush, or nearly flush, with the first side of the showerhead. The threaded nozzle insert 1000 also include a pair of spaced-apart spanner drive holes that are positioned on the top surface of the head portion on either side of the gas distribution port that extends through the threaded nozzle insert 1000. Such spanner drive holes allow, for example, a spanner screwdrive or spanner driver to be used to torque the threaded nozzle inserts 1000 into place during installation (or to remove them from the showerhead).

FIGS. 11A and 11B similarly depict isometric and cross-sectional views, respectively, of another example of such a threaded nozzle insert. The threaded nozzle insert 1100 is similar to the threaded nozzle insert 1000 except that instead of the spanner drive holes used in the threaded nozzle insert 1000, the threaded nozzle insert 1100 has a hexagonal recess in the middle that is sized to receive a hex driver or Allen key wrench, thereby allowing the threaded nozzle insert 1100 to be torqued during installation. The threaded nozzle insert 1100, like the threaded nozzle insert 1000, may be installed such that it is flush with the first side of the showerhead, thereby causing the underside of the showerhead to be smoother/flatter.

Semiconductor processing tools may be controlled with a controller that may be programmed to control various processes or parameters such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber. In the context of a controller that is used with the threaded nozzle inserts disclosed herein, such a controller may control various valves that may be activated to flow process gases through the threaded nozzle inserts, e.g., via a showerhead that the threaded nozzle inserts are installed in.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application-specific integrated circuits (ASICs), and/or one or more microprocessors or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. In the context of a controller used with a semiconductor processing system, the computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example threaded nozzle inserts according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

What is claimed is:

1. An apparatus comprising:
a head portion, wherein the head portion has a first face surface and a second face surface parallel to the first face surface and having an outer perimeter that is substantially the same size and shape as an outer perimeter of the first face surface;
a shaft portion extending from the second face surface, wherein:
a first sub-portion of the shaft portion is threaded along its length and has a diameter smaller than a maximum dimension of the second face surface, and
a gas distribution hole extends through the head portion and the shaft portion and along a direction perpendicular to the second face surface.

2. The apparatus of claim 1, wherein the gas distribution hole has a first diameter at at least one location in between the first face surface and the second face surface and a second diameter larger than the first diameter where the gas distribution hole exits the shaft portion.

3. The apparatus of claim 2, wherein the first diameter is between 0.005″ and 0.03″.

4. The apparatus of claim 3, wherein the second diameter is between 0.02″ and 0.14″.

5. The apparatus of claim 4, wherein the first sub-portion of the shaft portion is threaded with a 10-32 thread.

6. The apparatus of claim 5, wherein a second sub-portion of the shaft portion located in between the first sub-portion of the shaft portion and the second face surface has a diameter of 0.15″ or less.

7. The apparatus of claim 5, wherein a transition between the shaft portion and the head portion has a radius of 0.05″ or less.

8. The apparatus of claim 7, wherein a distance between the first face surface and the second face surface is between 0.03″ and 0.2″.

9. The apparatus of claim 8, wherein the shaft portion extends between 0.2″ and 0.3″ from the second face surface.

10. The apparatus of claim 1, wherein the head portion further includes at least two side surfaces that are interposed between the first face surface and the second face surface.

11. The apparatus of claim 10, wherein the outer perimeters of the first face surface and the second face surface are generally hexagonal in shape and there are at least six side surfaces, each side surface extending between straight sides of the outer perimeters of the first face surface and the second face surface.

12. The apparatus of claim 11, wherein the second face surface intersects with the six side surfaces at a chamfered edge.

13. The apparatus of claim 12, wherein the first face surface intersects with the six side surfaces at a rounded edge.

14. The apparatus of claim 11, further including six curved side surfaces, each curved side surface interposed between two of the six side surfaces and each curved side surface concentric and co-radial with the other curved side surfaces.

15. The apparatus of claim 1, wherein the head portion and the shaft portion are made from an aluminum alloy or from a ceramic.

16. The apparatus of claim 15, wherein the head portion and the shaft portion are made from a 6061-T6 aluminum alloy.

17. The apparatus of claim 1, wherein the first face surface of the head portion includes two spanner drive holes that extend into the head portion and are positioned such that the gas distribution hole is located in between the two spanner drive holes.

18. The apparatus of claim 17, wherein the spanner drive holes are larger than the gas distribution hole and do not intersect with the gas distribution hole.

19. The apparatus of claim 1, wherein the first face surface of the head portion includes a hexagonal recess that extends into the head portion.

20. The apparatus of claim 19, wherein the hexagonal recess is centered on the gas distribution hole and one end of the gas distribution hole terminates at the bottom of the hexagonal recess.
